(19) United States
(12) Patent Application Publication
(10) Pub. No.: US 2008/0282215 A1
(43) Pub. Date: Nov. 13, 2008

(54) METHOD OF DESIGNING A DIGITAL INTEGRATED CIRCUIT FOR A MULTI-FUNCTIONAL DIGITAL PROTECTIVE RELAY

(76) Inventors: Chia-Chi Chu, Kwei-Shan (TW); Feng-Li Lin, Kwei-Shan (TW)

Correspondence Address: Charles G. Mersereau;NIKOLAI & MERSERAU, P.A., # 820, 900 Second Ave. S., Minneapolis, MN, 55402, US

(21) Appl. No.: 11/747,471

(22) Filed: May 11, 2007

(51) Int. Cl. G06F 17/50; H03K 19/00

(52) U.S. Cl. 716/17

(57) ABSTRACT

This invention relates to a method of designing a digital integrated circuit for a multi-functional digital protective relay, emphasizing a digital module part, and input voltage and current signals are processed by a digital signal processor module to calculate the fundamental wave of the input voltage and current of protective relay, prevent the harmonic components in the input voltage or current from affecting the protective relay in operation; calculate for a root mean square value of voltage and current, being offered to a protective module next to determine a precise value, and the result is sent to the over voltage, under voltage, over current, and under current protective relay, the DSP using a pipeline-based structure, frequency-division fast Fourier transformation, and matrix spin digital algorithm to speed up the operation and reduce the occupied hardware area, which is a design for calculation and protection of the multi-functional digital protective relay.

### BACKGROUND OF THE INVENTION

1. Field of the Invention

This invention relates to a method of designing a digital integrated circuit for a multi-functional digital protective relay and particularly to a design for a protective relay from over voltage, under voltage, over current, and under current.

2. Description of Related Art

From the history of protective relay development, it is apparent that a digital protective relay came forth in year 1979, of which the design core was a microprocessor mainly applied at an initial stage for over current protection; besides, a microprocessor-based protective relay was designed for frequency detection.

In early year 1990s, an integrated protective relay system design was provided, in which the integration of application to multi-functional microprocessor-based protective relay for the fields of voltage, current, frequency and the like increases, a digital signal processing design being included.

However, the microprocessor-based protective relay must co-work with a plurality of integrated circuits for achievement of the protective relay design. It takes more time to debug the connections between integrated circuits on a design motherboard of which the volume is quite high and stability is lower, which is incompetent in huge calculation.

Consequently, because of the technical defects of described above, the applicant keeps on carving unflaggingly through wholehearted experience and research to develop the present invention, which can effectively improve the defects described above.

### SUMMARY OF THE INVENTION

This invention provides a method of designing a digital integrated circuit for a multi-functional digital protective relay. The digital integrated circuit for multi-functional digital protective relays comprises over voltage, under voltage, over current, and under current protective relays. Once a set of equipment fails in short circuit, a protective triggering signal may be automatically offered according to a specified protection value and the voltage and current may be calculated for its effective value and power, which is a design for calculation and protection of the multi-functional digital protective relays.

### BRIEF DESCRIPTION OF THE DRAWINGS

FIG. 1 is a view of the structure of a multi-functional protective relay according to this invention;

FIG. 2 is a view of the structure of a voltage and current protective relay module according to this invention;

FIG. 3 is a flow chart of a digital signal processor module design according to this invention;

FIG. 4 is a data flow chart of Fast Fourier Transform by frequency division according to this invention;

FIG. 5 is a view of the system of Fast Fourier Transform for pipeline-based Radix 2 Signal Path Delay Feedback (R2SDF) according to this invention; and

FIG. 6 is a flow chart of a digital silicon intellectual property design according to this invention.

### DETAILED DESCRIPTION OF THE PREFERRED EMBODIMENTS

Now, the present invention will be described more specifically with reference to the following embodiments. It is to be noted that the following descriptions of preferred embodiments of this invention are presented herein for purpose of illustration and description only; it is not intended to be exhaustive or to be limited to the precise form disclosed.

This invention provides a method of designing a digital integrated circuit for a multi-functional digital protective relay, comprising

step 1 of designing an internal digital signal processor module that uses the frequency-division fast Fourier transform as the basic structure of digital signal processor algorithm, transforming a voltage/current signal into a frequency domain for calculation of each index;

step 2 of designing the internal digital signal processor module to which a pipeline-based structure of fast Fourier Transform is added, the structure being called Radix 2 Signal Path Delay Feedback (R2SDF) that is provided for achievement of chip resource saving and system running speed exaltation;

step 3 of designing the internal digital signal processor module to which a matrix rotation digital algorithm is added instead of a complex divider inside the R2SDF, which is provided for increasing the usage efficiency of chip resource and achieving the operation result as effective as that given by a complex multiplier, the occupied area of chip being yet the quarter of complex multiplier;

step 4 of designing an internal rooting circuit module doing calculation for a root mean square value, and applying a new non-restoring rooting algorithm, the core of algorithm being an adder/subtracter and easily achieved in a field effect programmable logic array design because of low demand in hardware; and

step 5 of designing the digital signal processor module and the digital protective relay module that are verified through a field programmable logic gate array model for a digital integrated circuit for achievement of silicon intellectual property.

Thus, the digital integrated circuit for multi-functional digital protective relays comprises over voltage, under voltage, over current, and under current protective relays

Once a set of equipment fails in short circuit, a protective triggering signal may be automatically offered according to a specified protection value and the voltage and current may be calculated for its effective value and power, which is a design for calculation and protection of the multi-functional digital protective relays.

Besides, the structures are respectively described below.

Digital Protective Relay System Structure:

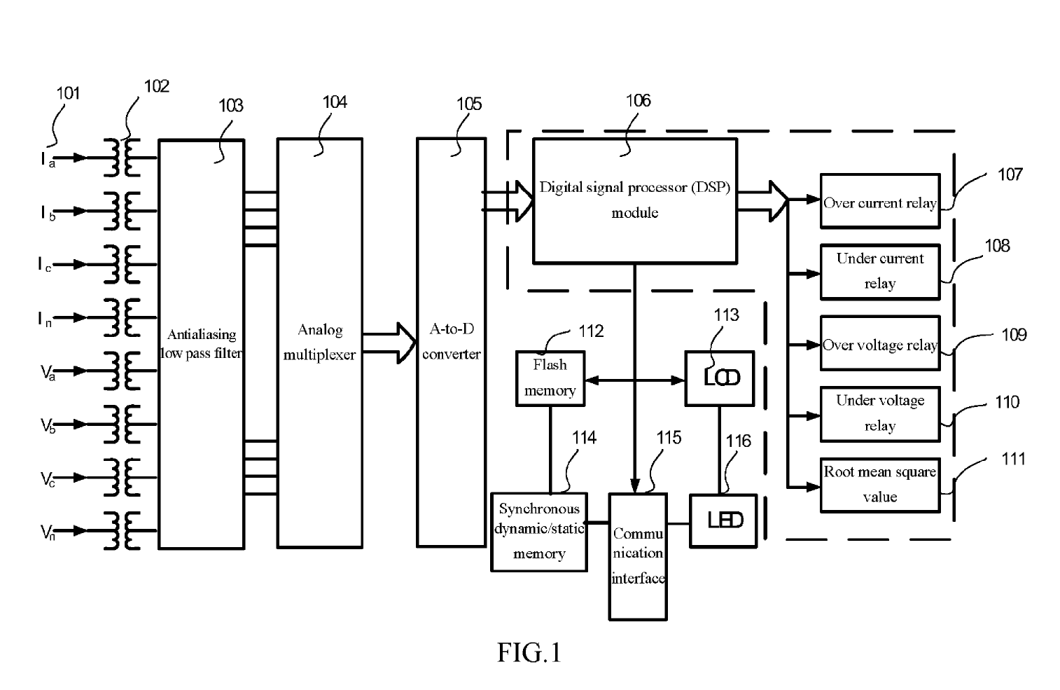

The whole system structure of multi-functional digital protective relay, as shown in FIG. 1, comprises an analog signal structure and a digital signal structure.
1. Analog module: a three-phase system for current and voltage uses a voltage transformer and current transformer 101 and a transformer 102 to extract an analog value; but system analog value must be further processed for the digital signal processor; thus, sampling/quantizing, an analog multiplexer 104, and A-to-D converter 105 are required, and in order to prevent extremely low sampling frequency and aliasing, an antialiasing low pass filter 103 must be added to filter the low pass composition for reducing noise.
2. Digital module: this block is the core of this invention, comprising a digital signal processor (DSP) module 106 and a protective relay module that composes an over current relay 107, an under current relay 108, an over voltage relay 109, an under voltage relay 110, and a root mean square value; in order to easily analyze power system quality, a time domain signal must be converted to a frequency domain signal, and baseband components and harmonic components extracted from the electric power signal revealed by the frequency domain are processed by a CPU for data and then are sent to the protective relay module to determine voltage breakout, frequency measurement, and harmonic analysis as relay protection drive for complete operation of the protective relay.
3. Peripheral module: a memory component and a peripheral display component are involved in this block, in which the memory component comprises a flash memory 112 and a synchronous dynamic/static memory 114; the peripheral display component comprises a LCD 113, a LED 116, and a communication interface 115; during digital signal processing, the memory components are required to register the values when the CPU processes a code required for operation, and its status is shown on the display component and given through the communication interface.

### Digital Protective Relay Module Design:

The protective relay module comprises the over current relay 107, the under current relay 108, the over voltage relay 109, the under voltage relay 110, and the root mean square value 111, and the four modules are the same in operation principle, as described below.

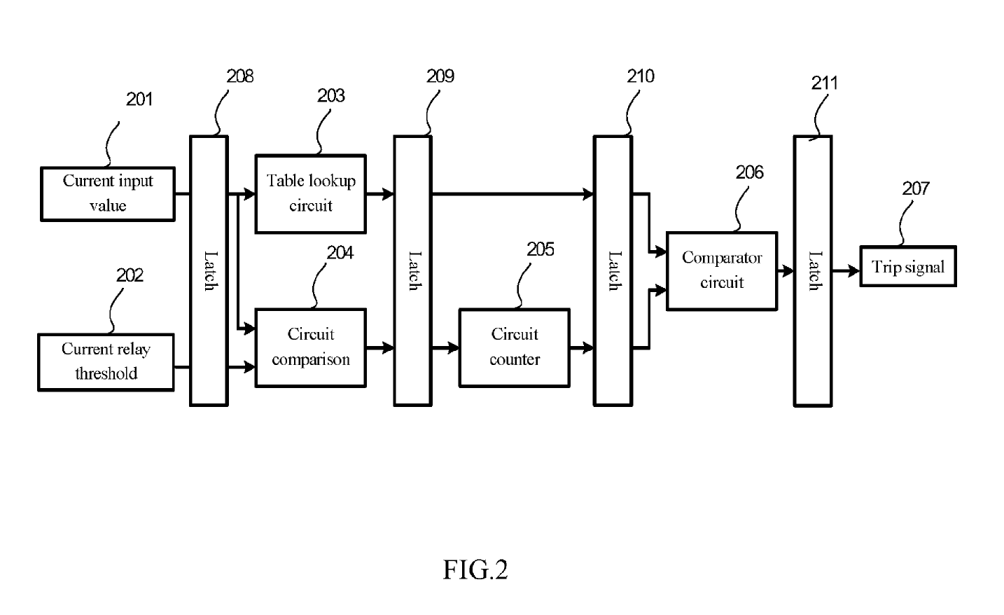

In this invention, a pipeline-based structure is designed, as shown in FIG. 2, which is divided and described at three stages.

At stage 1, there are a table lookup circuit 203 and a comparator circuit 204.

Firstly, two input signals are a current input value 201 and a current relay threshold 202. The current signal is sent to the table lookup circuit 203 to calculate for comparative delay time for storage in a latch 208; at the same time, the current input value 201 and the current relay threshold 202 are calculated in the comparator circuit 204, and an over current signal will be given from comparison; if there is over current, the over current signal is set to 1; if not, 0; two output values given at stage 1 are stored in a latch 209.

At stage 2, there is only a counter circuit 205. The over current signal is measured for a delay period, and if the over current protection signal is 1, the counter circuit 205 counts at all times, stores the value in a latch 210, and sends it to a next stage. Otherwise, if the over current protection signal is 0, the counter circuit 205 is set to 0; another table lookup value passes through this stage without any operation.

At stage 3, there is only a comparator circuit 206. If a value sent from the counter circuit 205 at stage 2 is larger than that sent from the table lookup circuit 203, a trip signal 207 will be sent; otherwise, it will not be sent.

### Digital Signal Processor Module Design:

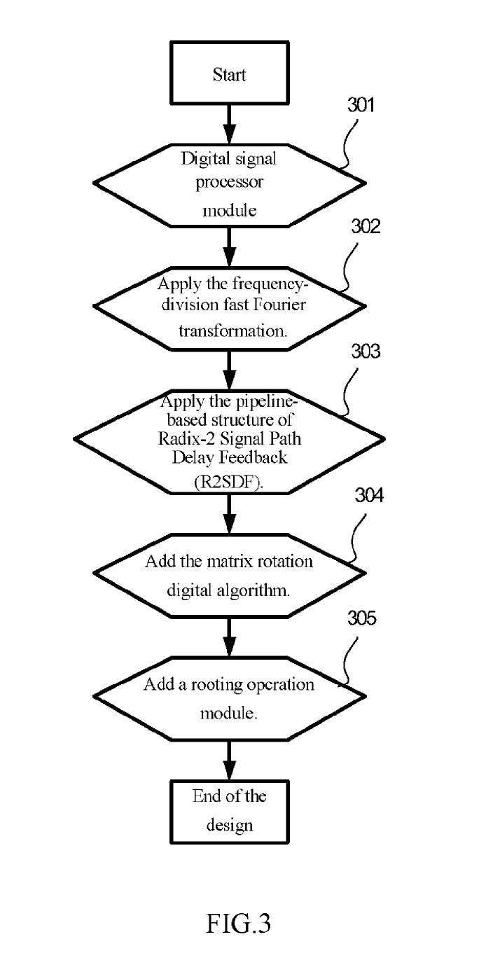

An input signal contains harmonic contents, in addition to a fundamental wave of the primary frequency of a power system. Thus, a digital signal processor module 301 is required in a SOC to calculate the fundamental wave of the input voltage and current of protective relay, prevent the harmonic components in the input voltage or current from affecting the protective relay in operation, and calculate for a root mean square value of voltage and current which is offered to a protective module at a next stage for determination of a precise value and may serve to detect the frequency, as shown in FIG. 3 and described below.

The fast Fourier transformation is an essential theory on signal processing, mainly functioning to transform time domain to frequency domain in the field of signal. When the power quality is analyzed, the time domain in the field of voltage or current signal may be transformed to the frequency domain, and calculation is further made for each index value and the degree of pollution applied to the signal, thereby driving the protective relay to work. Thus, a frequency-division fast Fourier transform structure 302 is provided in this invention to achieve the DSP module 301 in the protective relay.

In this invention, 32-point fast Fourier transformation is used as the core, and the processing order is not higher, so a butterfly-formed Radix-2 structure is used. A required hardware space is huge because 88 complex multipliers are required in the 32-point Radix-2 fast Fourier transformation structure, and the structure must thereby be adjusted; thus, a pipeline-based structure of Radix-2 Signal Path Delay Feedback (R2SDF) 303 is applied. A matrix rotation digital algorithm 304 is further added to reduce the occupied area of hardware and speed up the system running.

A fast Fourier transformation output signal contains real and virtual values, so the values must be accompanied with a rooting operation module 305 and divided by a \sqrt{2} circuit to be an effective value inputted from the protective relay.

Next, the pipeline-based structure of DSP chip and the rooting operation module algorithm are described below.

(1) Frequency-Division Fast Fourier Transformation

This module uses the 16-point Radix-2 frequency-division fast Fourier transform as the basic structure of digital signal processor algorithm, which is given from Discrete Fourier Transformation (DFT) that is expressed by a mathematical formula, as shown in equation (1):

$$X [ k ] = {\sum }_{n = 0}^{N - 1} x [ n ] {W}_{N}^{nk} , \\ k = 0 , 1 , … N - 1 \qquad ( 1 )$$

where W=e^{-jθ} and its even number item is first extracted

$$X [ 2 r ] = {\sum }_{n = 0}^{N - 1} x [ n ] {W}_{N}^{n ( 2 r )} , \\ r = 0 , 1 , … , ( N / 2 ) - 1 \\ X [ 2 r ] = {\sum }_{n = 0}^{N / 2 - 1} x [ n ] {W}_{N}^{2 nr} + {\sum }_{n = N / 2}^{N - 1} x [ n ] {W}_{N}^{2 nr} then = {\sum }_{n = 0}^{N / 2 - 1} ( x [ n ] + x [ n + ( N / 2 ) ] ) {W}_{N / 2}^{nr} , \\ r = 0 , 1 , … , ( N / 2 ) - 1. \qquad ( 2 )$$

likewise, it may prove that an odd number item is equation (3)

$$X [ 2 r + 1 ] = {\sum }_{n = 0}^{N / 2 - 1} ( x [ n ] - x [ n + ( N / 2 ) ] ) {W}_{N / 2}^{nr} {W}_{N}^{n} , \\ r = 0 , 1 , … , ( N / 2 ) - 1 \qquad ( 3 )$$

equations (4) and (5) may be changed from equations (2) and (3)

$$\begin{matrix}X [ 2 r ] = {\sum }_{n = 0}^{N / 2 - 1} g ( x ) {W}_{N / 2}^{rn} , \\ r = 0 , 1 , … , ( N / 2 ) - 1. & ( 4 ) \\ X [ 2 r + 1 ] = {\sum }_{n = 0}^{N / 2 - 1} f ( x ) {W}_{N / 2}^{nr} , \\ r = 0 , 1 , … , ( N / 2 ) - 1. \\ where \\ g ( x ) = x [ n ] + x [ n + ( N / 2 ) ] \\ f ( x ) = \{ x [ n ] - x [ n + ( N / 2 ) ] \} {W}_{N}^{n} & ( 5 )\end{matrix}$$

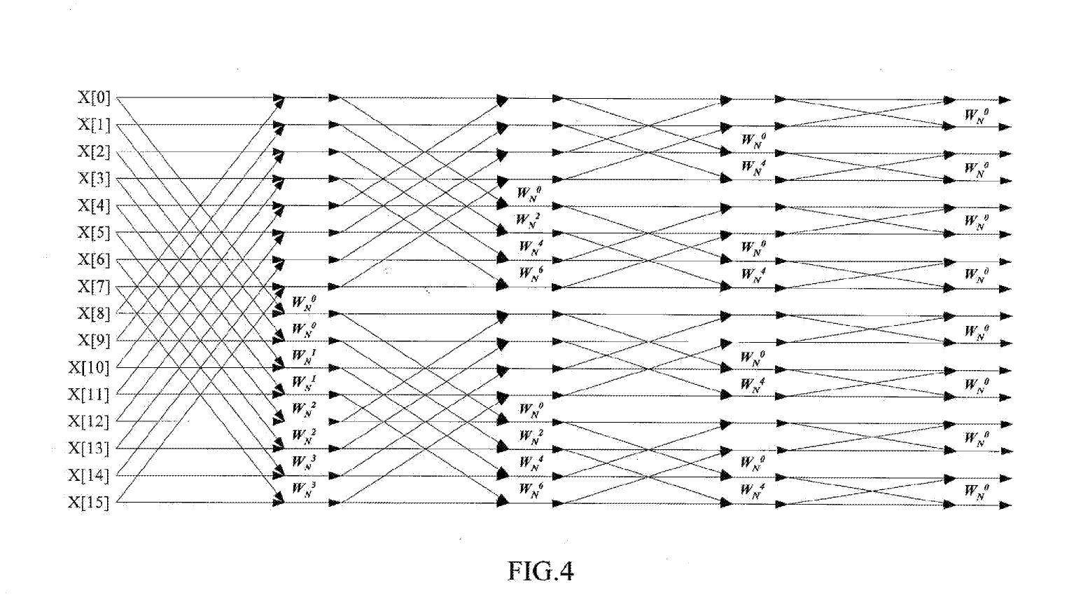

likewise, iteration being solved from equations (4) and (5), the frequency-division fast Fourier transform data stream structure is given, as shown in FIG. 4.

(2) Pipeline-Based Fast Fourier Structure

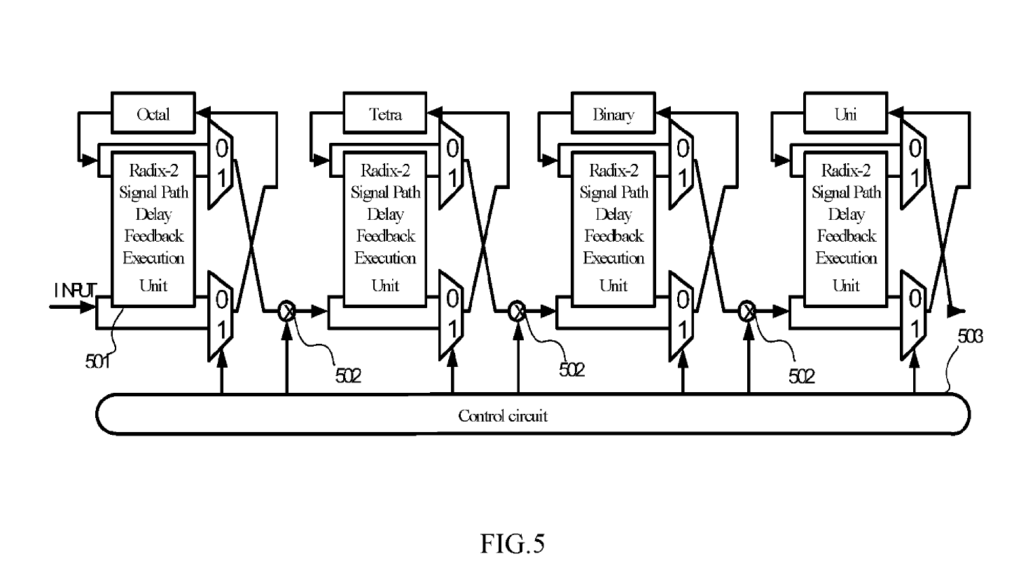

As shown in FIG. 4, the data apparent from the frequency-division fast Fourier transformation is a regular structure, data processing time is longer, and 32 complex multipliers is used. The area is over large and the data processing cycle is quite long. Thus, in order to reduce the chip area occupation rate and the data processing cycle, the pipeline-based structure of fast Fourier transformation is used, as shown in FIG. 5. This structure is named Radix-2 Signal Path Delay Feedback Execution Unit (PE) 501, and matching with 3 complex multipliers 502 and following a register accessing data, a control circuit 503 determine a direction of data flow; the pipeline-based structure of fast Fourier transformation is achieved to save the hardware resource and speed up the system running.

(3) Matrix Rotation Digital Algorithm

The complex multiplier is a unit of which the consumption of area resource is highest in the DSP module. In order to increase the performance of hardware resource, the matrix rotation digital algorithm is used instead of the complex divider in the Radix-2 Signal Path Delay Feedback Execution Unit. In a manner of specific-angle matrix spin, the operation result of matrix spin digital algorithm is so effective as that of complex multiplier; however, only quarter of the hardware area is less occupied than the complex multiplier. The occupied area is effectively

$${x}^{′} + j {y}^{′} = ( x + j y ) {e}^{- jθ} = ( x + j y ) ( cos θ - j sin θ )$$

reduced. It is assumed that a complex multiplication is expressed in the form of matrix, then

$$\begin{matrix}[ \begin{matrix}{x}^{′} \\ {y}^{′}\end{matrix} ] = [ \begin{matrix}cos θ & sin θ \\ - sin θ & cos θ\end{matrix} ] [ \begin{matrix}x \\ y\end{matrix} ] \\ [ \begin{matrix}{x}^{′} \\ {y}^{′}\end{matrix} ] = cos [ \begin{matrix}1 & tan θ \\ - tan θ & 1\end{matrix} ] [ \begin{matrix}x \\ y\end{matrix} ] & ( 6 ) \\ [ \begin{matrix}{x}_{i + 1} \\ {y}_{i + 1}\end{matrix} ] = \frac{1}{{\prod }_{i = 0}^{N - 1} \sqrt{1 + {2}^{2 i}}} [ \begin{matrix}1 & {u}_{i} {2}^{- i} \\ - {u}_{i} {2}^{- i} & 1\end{matrix} ] [ \begin{matrix}{x}_{i} \\ {y}_{i}\end{matrix} ] & ( 7 ) \\ {z}_{i + 1} = {z}_{i} - {u}_{i} {a}_{i} , \\ {u}_{i} = \{ 1 , - 1 \} & ( 8 )\end{matrix}$$

In equation (6), it is assumed that equation (7) may be given from

$$θ = {\sum }_{i = 0}^{N - 1} {u}_{i} {2}^{- i} ,$$

and thus an algorithm for large-angle spin may be achieved with a plurality small-angle spin. Further, the Radix of matrix operation is the quadratic of 2, so a shifter and an adder may be used in the hardware design to achieve the complex multiplication. As shown in equation (8), zᵢ is a specified spin angle and aᵢ=tan⁻¹ 2⁻¹ represents an angle at which the spin is done each time. When zᵢ₊₁ is larger than 0, the spin angle exceeds a specified angle, uᵢ=−1. On the other hand, When zᵢ₊₁ is smaller than 0, the spin angle does not exceed the specified angle, uᵢ=1, and it must be reduced to a remaining angle, in which the more the number of N is, the more the number of spin is; when a value given from calculation is very much precise and N tends to limitlessness, zᵢ₊₁ tends to 0.

(4) Root Circuit Structure for Related Digital Signal Processing

For the digital processing of protective relay, a root module is required and thus a new non-restoring rooting algorithm is applied. The core of algorithm is an adder/subtracter and easily achieved in a field effect programmable logic array design because of low demand in hardware. In this invention, calculation is done for 32-bit fixed point design, and according to an algorithm in which 16 times of recursion, a rooted value, a 16 bit root, and a 18-bit remainder may be given; this algorithm is expressed as follows:

```
Let
D be 32-bits unsigned integer
Q be 16-bits unsigned integer
R be 17-bits integer (R = D − Q² )
Algorithm :
Q = 0 R = 0;
for i = 15 to 0 do
  if (R ≧ 0)
    R = (R << 2)or(D >> (i + i) & 3);
    R = R − ((Q << 2)or1);
  else
    R = (R << 2)or(D >> (i + i) & 3);
    R = R − ((Q << 2)or3);
  endif
  it(R ≧ 0)then
    Q = (Q << 1)or1;
  else
    Q = (Q << 1)or0;
  endif
```

We let initial values of Q and R to be 0 and determine whether R is larger than or equal to 0; if yes, R shifts to two bits, the two uppermost values of value R in the intersection set are placed in R, then Q are subtracted from R, R shifts to two bits to which 1 is added, and then Q is placed in R.

Contrarily, 3 is added; next, R is determined, and if R is equal to 0, Q shifts to one bit to which 1 is added; otherwise no value is added.

### IMPLEMENTATION OF THE INVENTION

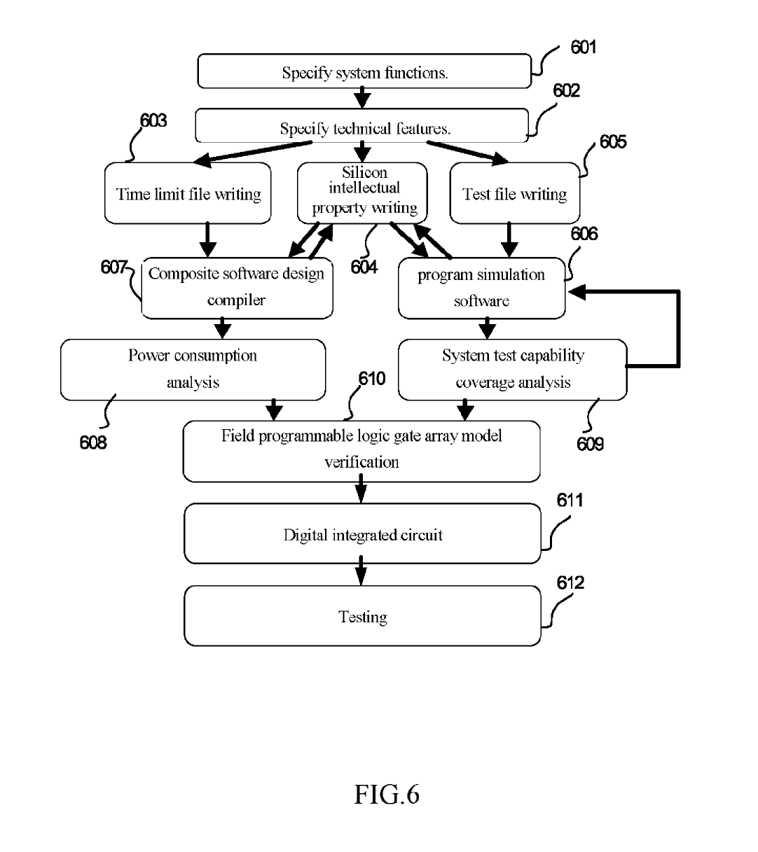

In this invention, each module is designed for silicon intellectual property; a design flow, as shown in FIG. 6, starts with specified system functions 601 and specified technical features 602.

Then, the design flow is branched into 3 design flows and they are time limit file writing 603, silicon intellectual property writing 604, and test file writing 605.

The time limit file writing 603 and the silicon intellectual property writing 604 are done through a set of program simulation software 606 for system function verification and system test capability coverage analysis 609.

The silicon intellectual property writing 604 and the test file writing 605 is done through a composite software design compiler 607 for system synthesis and then power consumption analysis 608.

Finally, they are loaded for the field programmable logic gate array model verification 610, and if the actual result and the simulation result are given without any error after comparison, a digital integrated circuit 611 may be created and then a test is performed 612.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of designing a digital integrated circuit for a multi-functional digital protective relay, comprising:
step 1 of designing an internal digital signal processor module and transforming a voltage/current signal into a frequency domain for calculation of each index;
step 2 of designing the internal digital signal processor module to which a pipeline-based structure of fast Fourier Transform is added, the structure being called Radix 2 Signal Path Delay Feedback (R2SDF) that is provided for achievement of chip resource saving and system running speed exaltation;
step 3 of designing the internal digital signal processor module to which a matrix rotation digital algorithm is added instead of a complex divider inside the R2SDF, which is provided for increasing the usage efficiency of chip resource and achieving the operation result as effective as that given by a complex multiplier;
step 4 of designing an internal rooting circuit module doing calculation for a root mean square value, and applying a new non-restoring rooting algoritin; and
step 5 of designing the digital signal processor module and the digital protective relay module that are verified through a field programmable logic gate array model for a digital integrated circuit for achievement of silicon intellectual property.

2. The method of designing the digital integrated circuit for the multi-functional digital protective relay according to claim 1, wherein the digital signal processor (DSP) module at step 1 uses the frequency-division fast Fourier transform as the basic structure of digital signal processor algorithm.

3. The method of designing the digital integrated circuit for the multi-functional digital protective relay according to claim 1, wherein the occupied area of chip at step 3 is yet the quarter of complex multiplier.

4. The method of designing the digital integrated circuit for the multi-functional digital protective relay according to claim 1, wherein the core of new non-restoring rooting algorithm at step 4 is an adder/subtracter and easily achieved in a field effect programmable logic array design because of low demand in hardware.
